(19) United States
(12) Patent Application Publication
(10) Pub. No.: US 2020/0049860 A1
(43) Pub. Date: Feb. 13, 2020

(54) LENS COATING FIXTURE

(71) Applicant: AAC Technologies Pte. Ltd., Singapore City (SG)

(72) Inventor: Chuandong Wei, Shenzhen (CN)

(21) Appl. No.: 16/533,790

(22) Filed: Aug. 7, 2019

(30) Foreign Application Priority Data
Aug. 10, 2018 (CN) 201821303528.6

(51) Int. Cl. G02B 1/10; C23C 14/50; C23C 16/458; G02B 7/02

(52) U.S. Cl. CPC G02B 1/10; C23C 14/50; C23C 14/35; G02B 7/021; C23C 16/458

(57) ABSTRACT

A lens coating fixture includes an upper plate and a lower plate disposed to be opposite to the upper plate and holding the lens to be coated together. The upper plate is provided with a plurality of first lens receiving holes, the lower plate is provided with a second lens receiving hole corresponding to each of the first lens receiving holes, and the upper plate is provided with a recess portion surrounding the first lens receiving hole. The recess portion is in communication with the first lens receiving hole. The lower plate is provided with a protrusion portion at a position corresponding to the recess portion. The protrusion portion is embedded in the recess portion and abuts against an object side or an image side of a non-imaging region of the lens to be coated.

### FIELD OF THE DISCLOSURE

The present disclosure relates to the field of lens coating, and in particular, relates to a lens coating fixture.

### DESCRIPTION OF RELATED ART

Coating processes are widely used such industries as metal machining industry, semiconductor industry, and optoelectronic industry and on the like. In recent years, with the rapid development of the semiconductor industry and the optoelectronic industry, the coating tecnhiques are drastically improved.

A coating fixture generally refers to a type of coating device suitable for coating processes to be carried out and performed under a higher vacuum degree. In the related art, many coating processes are available, such as vacuum ion evaporation, magnetron sputtering, molecular beam epitaxy (MBE), pulsed laser deposition (PLD) and the like.

In the coating processes, coating in the photoelectric industry refers to a physical or chemical method of coating a single layer or a multilayer thin film on the surface of an optical element, and implementing focusing, calibration, filtering, reflection and refraction based on an interference effect exerted by light incidence, reflection and transmission on the interface of the thin film.

The lens coating fixture in the related art provides a plurality of lens receiving holes on an upper plate and an lower plate of the fixture to receive the lens. The process of coating the lens is as follows. Firstly, the lens to be coated is completely received in the lens receiving hole of the upper plate of the fixture, and then the lower plate of the fixture is fixedly attached to the upper plate of the fixture, and finally the lens is coated.

However, when the above-mentioned lens coating fixture is used, the upper plate and the lower plate of the fixture are easily deformed. The structure of the lens receiving hole alone may not fix the lens well. A plurality of lenses placed in the plurality of lens receiving holes may not be firmly fixed due to the deformation of the upper plate and the lower plate of the fixture, resulting in material scattering.

Therefore, it is desired to provide a lens coating fixture to overcome the above problem.

### BRIEF DESCRIPTION OF THE DRAWINGS

Various aspects of an exemplary embodiment may be better understood with reference to the accompanying drawings. Components in the drawings are not necessarily drawn to scale, and the emphasis is instead placed upon clear illustration of the principles of the present disclosure. Moreover, in the drawings, like reference numerals designate corresponding parts throughout the drawings.

FIG. 1 is a schematic isometric structural view of a lens coating fixture according to a first embodiment of the present disclosure;

FIG. 2 is a perspective view of the lens coating fixture taken from another angle according to the first embodiment of the present disclosure;

FIG. 3 is a top view of the lens coating fixture according to the first embodiment of the present disclosure;

FIG. 4 is a perspective view taken along line A-A in FIG. 3;

FIG. 5 is an enlarged view of part C in FIG. 4; and

FIG. 6 is a partial perspective view taken along line B-B in FIG. 3.

### DETAILED DESCRIPTION

The present disclosure is described in detail hereinafter with reference to an exemplary embodiment. For clearer descriptions of the technical solution and beneficial effects of the present disclosure, the present disclosure is described in further detail with reference to the accompanying drawings and exemplary embodiment. It should be understood the exemplary embodiment described hereinafter is only intended to illustrate the disclosure, but not intended to limit the present disclosure.

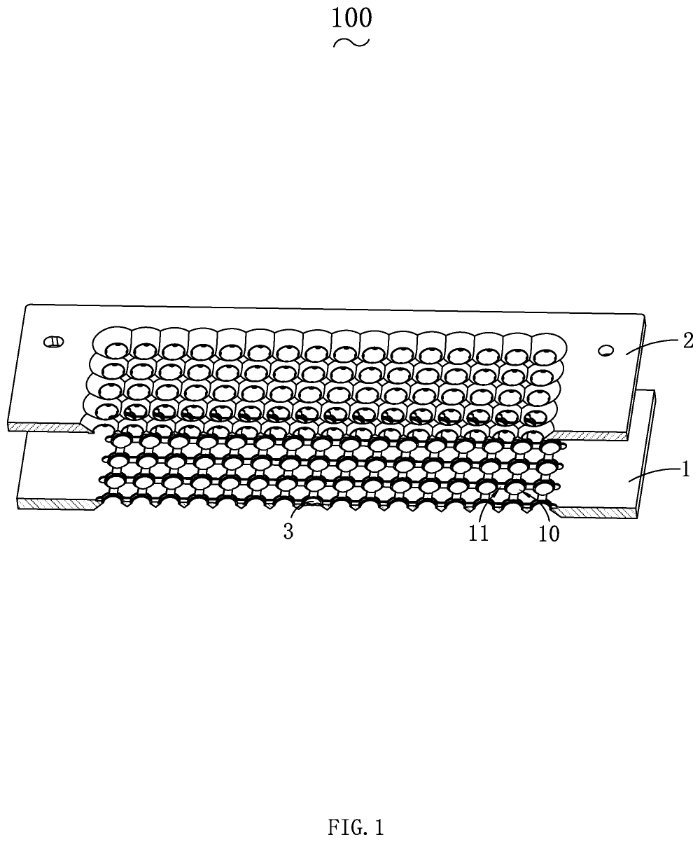

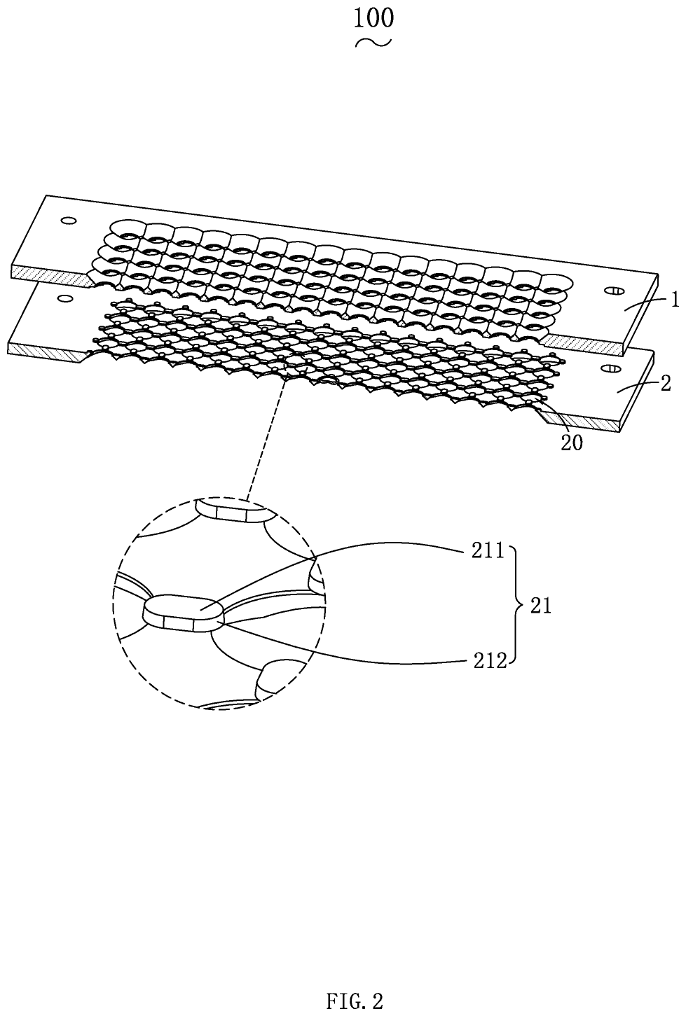

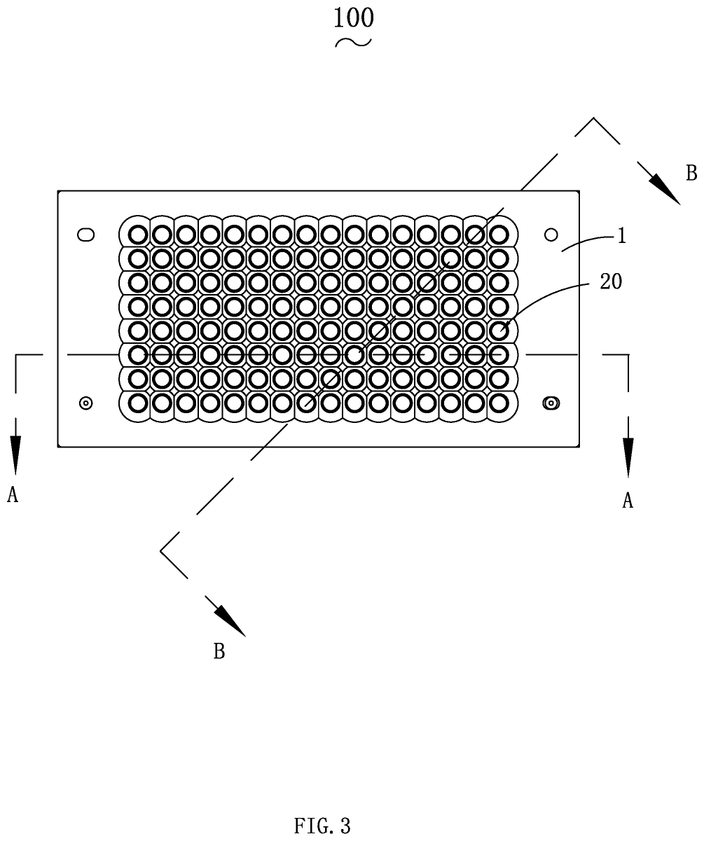

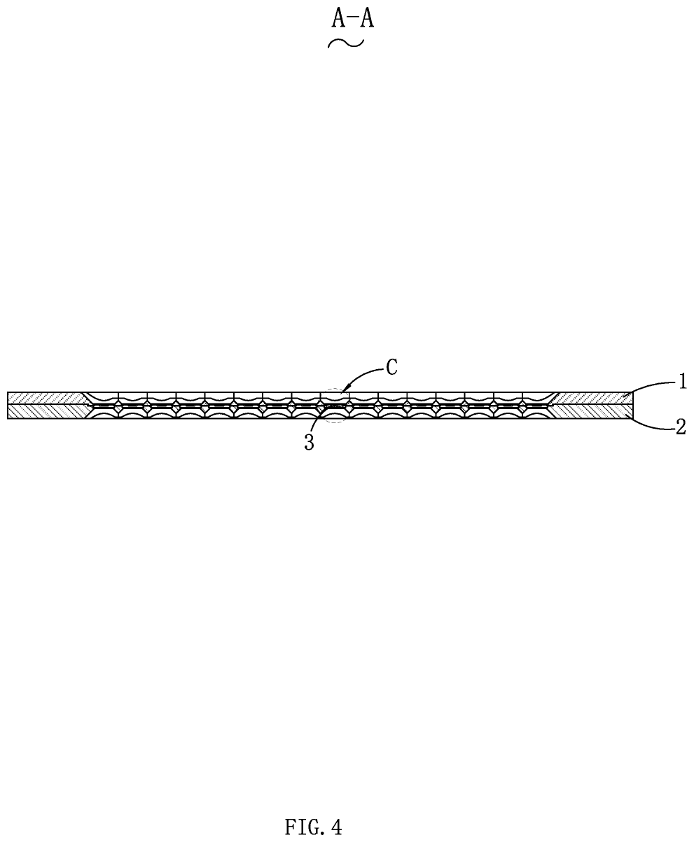

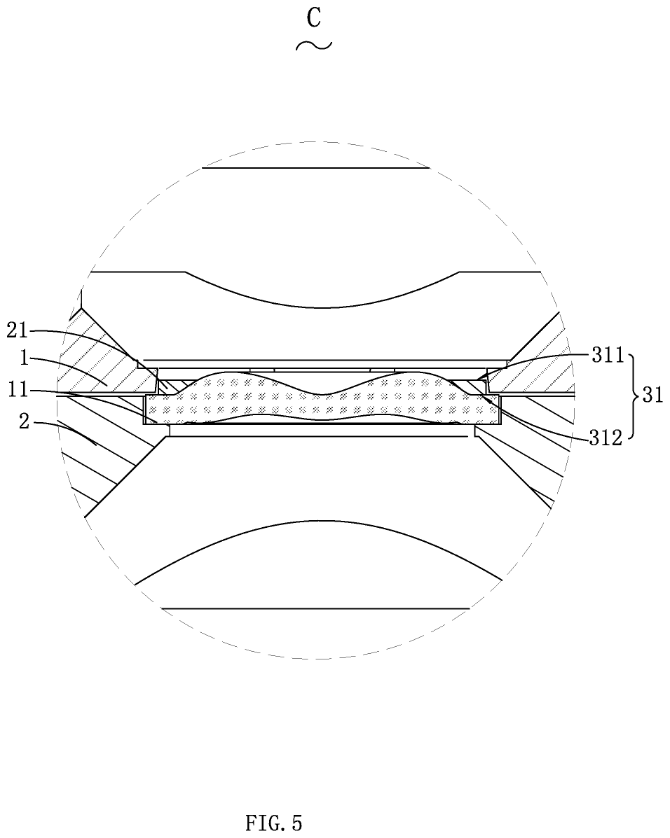

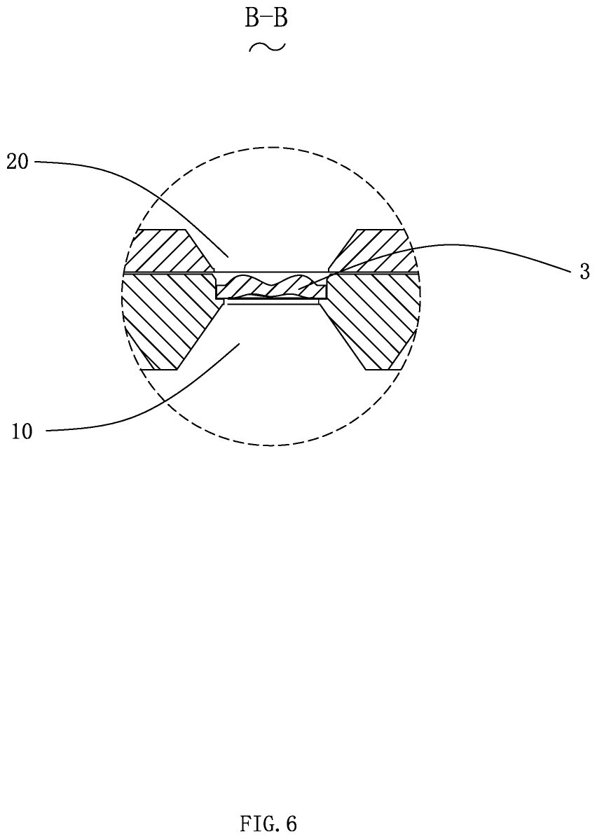

Referring to FIG. 1 to FIG. 6, FIG. 1 is a schematic isometric structural view of a lens coating fixture according to a first embodiment of the present disclosure; FIG. 2 is a perspective view of the lens coating fixture taken from another angle according to the first embodiment of the present disclosure; FIG. 3 is a top view of the lens coating fixture according to the first embodiment of the present disclosure; FIG. 4 is a perspective view taken along line A-A in FIG. 3; FIG. 5 is an enlarged view of part C in FIG. 4; and FIG. 6 is a partial perspective view taken along line B-B in FIG. 3. The present disclosure provides a lens coating fixture 100 for coating a lens 3 to be coated. The lens coating fixture includes an upper plate 1 and a lower plate 2 disposed to be opposite to the upper plate 1. The upper plate 1 is provided with a plurality of first lens receiving holes 10 and a recess portion 11 surrounding the first lens receiving holes 10. The lower plate 2 is provided with a plurality of second lens receiving holes 20 corresponding to the first lens receiving holes 10 and a protrusion portion 21 corresponding to the recess portion 11. An aperture of the second lens receiving hole 20 is greater than an aperture of the lens 3 to be coated. The protrusion portion 21 is spaced apart from the second lens receiving holes 20.

When the upper plate 1 and the lower plate 2 are attached to each other, the protrusion portion 21 is fitted into the recess portion 11 and abuts against an object side surface 311 or an image side surface 312 of a non-imaging region 31 of the lens 3. The lens 3 to be coated is attached to an inner wall of the first lens receiving holes 10.

Compared with the related art, since the lens receiving hole is provided on the upper plate 1 and the lower plate 2, the lens can be placed on the upper plate 1 or the lower plate 2 so as to detect the appearance of the lens. Meanwhile, the recess portion 11 is disposed on the upper plate 1, and the protrusion portion 21 is disposed on the lower plate 2 at the position corresponding to the recess portion 11. The protrusion portion 21 is spaced apart from the second lens receiving holes 20. When the upper plate 1 and the lower plate 2 are attached to each other, the protrusion portion 21 is embedded in the recess portion 11 and abuts against the object side surface 311 or the image side surface 312 of the non-imaging region 31 of the lens 3 to be coated.

In this way, the stability between the lens coating fixture 100 and the lens 3 to be coated may be improved by abutment between the lens 3 to be coated and the protrusion portion 21, and the embedment and fixing between the protrusion portion 21 and the recess portion 11.

When the upper plate 1 and the lower plate 2 are deformed, the lens still abuts against the protrusion portion 21 embedded in the recess portion 11, and thus the lens may not be loosened due to the fixing effect of the lens receiving hole, thereby avoiding material scattering during the lens coating process.

It is to be noted that, in this embodiment, the protrusion portion 21 extends into the second lens receiving holes 20 in an radial direction of the second lens housing hole 20. With this configuration, a diameter of the second lens receiving hole 20 may be made greater than an outer diameter of the lens 3 to be coated. Furthermore, as illustrated in FIG. 2, a projection of the protrusion portion 21 on the upper plate 1 at least partially falls within the first lens receiving holes 10.

Referring to FIG. 3 to FIG. 5, in this embodiment, a plurality of recess portions 11 are arranged, and the plurality of recess portions 11 are equally spaced around the first lens receiving holes 10. A plurality of protrusion portions 21 are arranged, and the plurality of protrusion portions 21 are equally spaced around the second lens receiving holes 20. The recess portions 11 are one-to-one correspond to the protrusion portions 21. The equal spacing between the plurality of recess portion 11 and the protrusion portion 21 applies a uniform force to the lens to be coated uniform, thereby avoiding the shaking of the lens to be coated during the working process of the lens coating fixture 100, and improving the stability between the lens coating fixture 100 and the lenses 3 to be coated. With the equally spaced recess portion 11 and the protrusion portion 21, operations by the lens coating fixture 100 are simpler.

It may be understand that for further preventing the lens coating fixture 100 from being loosened during operation of separating the lens from the upper plate 1, in this embodiment, a height of the protrusion portion 21 may be adjusted according to actual conditions, such that a contact area between the protrusion portion 21 and the lens 3 to be coated is increased by increasing the height of the protrusion portion 21, thereby enhancing the protrusion portion 21 abutting action with the lens 3 to be coated.

Specifically, the plurality of recess portions 11 are respectively in communication with the adjacent first lens receiving holes 10, and the plurality of protrusion portions 21 are respectively disposed between the adjacent second lens receiving holes 20. With this structure of the recess portion 11, the operations are more convenient, and the lens coating fixture 100 has a good appearance effect.

Specifically, the protrusion portion 21 includes an end surface 211 distal from the lower plate 2 of the lens coating fixture 100, and a side wall 212 extending from the end surface 211 towards the lower plate 2 of the lens coating fixture 100. The end surface 212 is configured to abut against the object side surface 311 or the image side surface 312 of the non-imaging region 31 of the lens 3 to be coated when the upper plate 1 and the lower plate 2 are attached to each other.

It can be understood that the protrusion portion 21 may be integrally formed with the lower plate 2 of the fixture 100, and the integrally formed protrusion portion 21 and the lower plate 2 of the fixture 100 are structurally stable. Nevertheless, the protrusion portion 21 and the lower plate 2 of the fixture 100 may also be independently processed, and then the protrusion portion 21 is fixed on the lower plate 2 of the fixture, such that the modification process is simplified when it is necessary to increase the height of the protrusion portion 21, and the protrusion portion 21 only needs to be removed and replaced with a height. The high protrusion portion 21 is sufficient.

It should be noted that, in this embodiment, the end surface 211 configured to abut against the object side surface 311 or the image side surface 312 is a flat surface. Since the object side surface 311 or the image side surface 312 of the non-image forming area 31 of the lens is also flat, the arrangement is made such that the contact area between the lens 3 to be coated and the protrusion portion 21 is increased, and the lens 3 and the side wall 212 are also coated. No gap is defined therebetween, such that a uniform force is applied to the lens 3 to be coated, and the lens 3 to be coated is effectively prevented from being damaged due to an uneven force.

Preferably, the plurality of first lens receiving holes 10 and the plurality of second lens receiving holes 20 are evenly arranged in an array.

It is worth mentioning that the lower plate 2 in this embodiment is provided with a holding hole 22, and the upper plate 1 is provided with a holding portion 12. When the upper plate 1 and the lower plate 2 are attached to each other, the holding hole 22 is held in the holding portion 12. Those skilled in the art can understand that the holding portion 12 can also be disposed on the lower plate 2, and the holding hole 22 is provided on the upper plate 1, which does not affect the effect of the present disclosure. It is very convenient to connect the upper plate 1 to the lower plate 2 by combination and assembly of the holding hole 22 and the holding portion 12, which facilitates the subsequent coating work, reduces the workload of the workers and improves the work efficiency.

Compared with the related art, the lens coating fixture according to present disclosure has a recess portion disposed on the upper plate, and the lower plate is provided with a protrusion portion corresponding to the recess portion. When the lower plate of the fixture and the lower plate are attached together, the protrusion portion is embedded in the recess portion and abuts against the object side surface or the image side surface of the non-imaging region of the lens to be coated, thereby improving the stability between the coating fixture and the lens to be coated by the abutting action of the lens to be coated and the protrusion portion and the fixedly embedding between the protrusion portion and the recess portion. When the upper plate and the lower plate are deformed, the lens still abuts against the protrusion portion embedded in the recess portion, and the fixing effect of the receiving hole is still maintained. Material scattering may be avoided during the lens coating process.

It is to be understood, however, that even though numerous features and advantages of this embodiment have been set forth in the foregoing description, together with details of the structures and functions of the embodiment, the present disclosure is illustrative only, and changes may be made in detail, especially in matters of shape, size, and arrangement of parts within the principles of the present disclosure to a full extent indicated by the general meaning of the terms in which the appended claims are expressed.

What is claimed is:

1. A lens coating fixture, comprising:
an upper plate, comprising:
a plurality of first lens receiving holes; and
a recess portion surrounding the first lens receiving holes;
a lower plate which is opposite to the upper plate and jointly clamps a lens to be coated with the upper plate, the lower plate comprising:
a plurality of second lens receiving holes corresponding to the first lens receiving holes; and
a protrusion portion corresponding to the recess portion, and an aperture of the second lens receiving hole being greater than an aperture of the lens to be coated;
wherein when the upper plate and the lower plate are attached to each other, the protrusion portion is fitted into the recess portion and abuts against an object side surface or an image side surface of a non-imaging region of the lens to be coated, and the lens to be coated is attached to an inner wall of the first lens receiving holes.

2. The lens coating fixture according to claim 1, wherein a plurality of recess portions are arranged, and the recess portions are arranged at an equal spacing around the first lens receiving hole, and a plurality of protrusion portions, the protrusion portions are arranged at an equal spacing around the second lens receiving hole, and the recess portions correspond to the protrusion portions one by one.

3. The lens coating fixture according to claim 2, wherein the plurality of recess portions are respectively in communication with adjacent first lens receiving holes, and the plurality of protrusion portions are respectively disposed between adjacent second lens receiving holes.

4. The lens coating fixture according to claim 1, wherein the protrusion portion includes an end surface distal from the lower plate and a side wall extending from the end surface towards the lower plate, the side wall being configured to abut against the object side surface or the image side surface of the non-imaging region of the lens when the upper plate and the lower plate are attached to each other.

5. The lens coating fixture according to claim 4, wherein a surface of the side wall that abuts against the object side surface or the image side surface of the lens to be coated is a flat surface.

6. The lens coating fixture according to claim 1, wherein the plurality of first lens receiving holes and the plurality of second lens receiving holes are evenly arranged in an array.

7. The lens coating fixture according to claim 1, wherein the protrusion portion is integrally formed with the lower plate.

8. The lens coating fixture according to claim 1, wherein the protrusion portion and the lower plate are separated structures.

9. The lens coating fixture according to claim 1, wherein one of the upper plate and the lower plate is provided with a holding portion, and the other is provided with a holding hole, the holding portion being held by the holding hole when the upper plate and the lower plate are attached to each other.

10. The lens coating fixture according to claim 1, wherein the protrusion portion is spaced apart from the second lens receiving holes.
